(19) United States
(12) Patent Application Publication
(10) Pub. No.: US 2008/0153040 A1
(43) Pub. Date: Jun. 26, 2008

(54) Method for processing semiconductor wafer

(75) Inventor: Nozomi Honda, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/000,614

(22) Filed: Dec. 14, 2007

(30) Foreign Application Priority Data
Dec. 21, 2006 (JP) 344520/2006
Oct. 29, 2007 (JP) 280259/2007

(51) Int. Cl. G03F 7/40; G03F 7/00

(52) U.S. Cl. 430/319; 430/401

(57) ABSTRACT

In a rework process for removing an organic film containing silicon formed on a semiconductor wafer substrate, silicon compound residues were generated, and it was difficult to remove them. In the present invention, the semiconductor wafer is processed by the method comprising at least: a first step of cleaning treatment, using an ammonia aqueous solution, of a surface exposed by removing an organic film containing silicon formed on the semiconductor wafer substrate; and a second step of cleaning treatment, using a diluted fluorinated acid aqueous solution. The ammonia concentration of the ammonia aqueous solution is preferably equal to or more than 0.01 weight percent and equal to or less than 30 weight percent. The fluorinated acid concentration of the diluted fluorinated acid aqueous solution is preferably equal to or more than 0.01 weight percent and equal to or less than 2.0 weight percent.

This application is based upon and claims the benefits of priorities from Japanese patent application No. 2006-344520, filed on Dec. 21, 2006 and Japanese patent application No. 2007-280259, filed on Oct. 7, 2007, the disclosures of which are incorporated herein in their entirety by reference.

### BACKGROUND OF THE INVENTION

1. Field of the Invention

The present invention relates to a method for processing a semiconductor wafer in a lithography step of a semiconductor manufacture process, and in particular to a method for removing a photoresist film (hereinafter, called “resist” for simplicity) or an organic film in a rework process.

2. Description of the Related Art

Semiconductor integrated circuits will continue to be increasingly highly integrated, and at the present day, the research and development for the purpose have been actively promoted. To achieve a higher degree of integration, the most effective method is that a line width of circuit patterning is made narrower in a semiconductor manufacture process. The circuit patterning is determined mainly by the shrinking ability of a lithography step, so that improving the resolution of lithography is the most effective method to highly integrate a semiconductor device. As one approach to improving the resolution of lithography, there has been proposed a multilayer resist process that another resist be further laminated on an organic film (including a resist). Further, one of the multilayer resist processes, in which two resist films are stacked, is specially called “bilayer process”.

To improve exposure resolution by using the same resist, it is effective to reduce a film thickness of the resist to be exposed. The multilayer resist process basically makes the resist to be exposed thinner and thereby achieve a high resolution.

However, when the resist to be exposed is made thinner as described above, the resist has to have a sufficient resistance as a mask when an organic film in a lower layer is etched by oxygen plasma or fluorine plasma etc. in a subsequent step, or as a mask used for etching an original object to be processed that is a further lower layer, such as a metal film or a silicon oxide film. That is, since the resist is used as a mask for etching a film in a lower layer, the resist has to have a resistance to etching necessary to remove the film in a lower layer. However, a chemical amplification type resist, which is nowadays used for high resolution application, generally has a low resistance to etching, and situations are that, as the resist film thickness is made thinner, the resist increasingly cannot endure etching applied to the film in a lower layer.

Then, to enhance the resistance of a resist to etching, a photoresist containing silicon such as a polysiloxane chemical amplification resist has been proposed. The polysiloxane chemical amplification resist may include, for example, a resist prepared by blending a chemical amplification resist composed of a resist composition having a silicon atom in a main chain and using a siloxane polymer containing an acid decomposition group such as an acetal structure, an ester structure, a butyloxycarbonyl structure, and a photoacid generator, with a polysiloxane having a silicon atom in a main chain and containing a silanol structure in a molecule. Besides the polysiloxane resist, a polysilane resist, a carbosilane resist and an acrylic polymer resist having a functional group containing silicon may be listed. The photoresist containing silicon has a high resistance to etching, and when the resist is made thinner, a necessary resistance to etching can be provided.

On the other hand, a semiconductor manufacture process includes a so-called “rework process” for removing a resist or an organic film once applied on the object to be processed, and carrying out a lithography step again from the beginning. Regarding technologies associated with a removal process for removing a resist or an organic film when the photoresist containing silicon is used, there are methods disclosed in Japanese Patent Application Laid-Open Nos. 2004-177669, 2005-285989, 2005-189660 and 2004-95899.

### SUMMARY OF THE INVENTION

However, in a rework process when a photoresist containing silicon is used, there has been a problem that it is difficult to completely remove residual silicon compounds produced after undergoing dissolution removal by exposure or an organic solvent, or an oxygen plasma ashing step.

It is not clearly known why the residual silicon compounds are produced, but it is thought as follows. That is, it is thought that, when exposure and development, dissolution by an organic solvent, or oxygen ashing are performed, silicon in the photoresist containing silicon drops out from a resin chain of the resist, so that this turns into the basis, and silicon compounds such as compounds produced from combination of silicon and an organic compound, or substances generated from oxidization of silicon are generated, and then they are not removed away and remain to constitute residues. In a rework process, because, after that, steps are done again from a formation step of a resist or an organic film, it is necessary to completely remove a photoresist, an organic film, a residue or the like, which will form a mask. It is not allowed to easily remove the silicon compound residues in a dissolution removal process using an organic solvent such as thinner removal, or ashing by oxygen plasma, which causes a problem that a restart of a lithography step, that is, a rework process is difficult.

Further, in a multilayer resist process where a conventional resist not containing silicon is used for an object to be exposed, and for a lower layer thereof, an organic film containing silicon is used, a similar problem also arises.

FIGS. 3A to 3C and 4A to 4D illustrate the problem.

FIGS. 3A to 3C are cross-sectional views illustrating in sequence a removal process for a rework process in a bilayer process in which a lower layer organic film and a photoresist containing silicon are used.

FIG. 3A shows a state after forming a work film 700 to be processed that is a metal film for constituting wirings or an insulating film such as a silicon oxide film on a semiconductor wafer 100, applying a lower layer organic film 200 and a photoresist containing silicon 300, and exposing and developing the photoresist containing silicon 300. At this time, silicon compound residues have yet not been generated.

The photoresist containing silicon 300 may include, for example, a polysiloxane chemical amplification resist, or in addition to this, a polysilane resist, a carbosilane resist, or an acrylic polymer resist having a functional group containing silicon. The polysiloxane chemical amplification resist may include, for example, a resist prepared by blending a chemical amplification resist composed of a resist composition having a silicon atom in a main chain and using siloxane polymer containing an acid decomposition group such as an acetal structure, an ester structure and a butyloxycarbonyl structure, and a photoacid generator, with a polysiloxane having a silicon atom in a main chain and containing a silanol structure in a molecule.

The lower layer organic film 200 may include, for example, a film having polyhydroxystyrene resin as a main component and prepared by adding a crosslinking agent etc. to an organic solvent such as propylene glycol monomethyl ether acetate or ethyl lactate.

Next, as shown in FIG. 3B, the photoresist containing silicon 300 is removed by thinner treatment. The thinner treatment is a step of dissolution removal of a photoresist using an organic solvent. As the organic solvent, for example, propylene glycol monomethyl ether acetate, propylene glycol monomethyl ether, γ-prolactin, ethyl lactate, isopropanol, or a mixture liquid thereof may be used. After undergoing the step, as shown in FIG. 3B, silicon compound residues 400 are generated on the surface of the lower layer organic film 200.

Then, as shown in FIG. 3C, the lower layer organic film 200 is removed by a step of oxygen plasma ashing treatment. Also after the step of oxygen plasma ashing treatment, the silicon compound residues 400 generated in the step shown in FIG. 3B are not removed but remain on the work film 700 to be processed.

Subsequently, a lower layer organic film and a photoresist containing silicon are again applied to proceed to a lithography step for rework (not shown).

FIGS. 4A to 4D are cross-sectional views illustrating in sequence a removal process for rework in a multilayer resist process in which a lower layer organic film, an organic film containing silicon and a photoresist are used.

FIG. 4A shows a state after forming a work film 700 to be processed that is a metal film for constituting wirings, or an insulating film such as a silicon oxide film on a semiconductor wafer 100, applying a lower layer organic film 200, an organic film containing silicon 500 and a photoresist not containing silicon 600, and exposing and developing the photoresist not containing silicon 600. At this time, silicon compound residues have yet not been generated.

As the organic film containing silicon 500, a polysilane organic composition, a siloxane organic composition, or an organic composition prepared by blending an organic composition composed of novolak resin or acrylic polymer with polysiloxane or polysilane may be listed.

Next, as shown in FIG. 4B, the photoresist not containing silicon 600 is dissolved and removed by thinner treatment. Because the photoresist not containing silicon 600 does not contain silicon, even after undergoing the step, silicon compound residues are not generated.

Then, as shown in FIG. 4C, the organic film containing silicon 500 is etched and removed by plasma etching using a fluorocarbon gas. After undergoing the step, the silicon compound residues 400 are generated on the surface of the lower layer organic film 200.

Then, as shown in FIG. 4D, the lower layer organic film 200 is removed by the step of oxygen plasma ashing treatment. Also after the step of oxygen plasma ashing treatment, the silicon compound residues 400 generated in the step shown in FIG. 4C are not removed but remain on the work film 700 to be processed.

Subsequently, a lower layer organic film, an organic film containing silicon and a photoresist are again applied to proceed to a lithography step for rework (not shown).

As described above, when an organic film containing silicon or a photoresist containing silicon are used, in a so-called “rework process” in which a resist, an organic film containing silicon or an organic film in a lower layer once applied are removed to carry out a lithography step again, there has been a problem that it was difficult to completely remove silicon compound residues generated after undergoing a step such as exposure or oxygen plasma ashing. These silicon compound residues cannot be easily removed by dissolution removal using an organic solvent such as thinner removal, or ashing by oxygen plasma, so that there arises a problem that it is difficult to carry out a lithography step again, that is, to rework. That is, after undergoing a rework process with the silicon compound residues remaining, an obstacle to exposure, a bit of dust in a process, and an unintended mask upon etching are generated, which causes failure or decreases reliability of a device.

Also, it is possible to remove the silicon compound residues 400 by cleaning using a chemical solution for etching a silicon oxide film, an ammonium hydroxide/hydrogen peroxide/water mixture (composition: NH₄OH/H₂O₂/H₂O; abbreviation: APM), a sulfuric acid/hydrogen peroxide/water mixture (composition: H₂SO₄/H₂O₂, abbreviation: SPM), or the like.

However, when the work film 700 to be processed is a silicon oxide film, a chemical solution having a high etching speed of a silicon oxide film cannot be used in rework. Further, when the work film 700 to be processed is a metal film such as tungsten, aluminum, or titanium, these metals are dissolved by use of SPM cleaning or APM cleaning, to contaminate the semiconductor wafer substrate. Therefore, these chemical solutions cannot be used.

Then, it is still the case that a practical method used in rework for removing an organic film or a resist cannot be found.

The present invention provides an effective solution to the problem. In addition, terms “organic film containing silicon” used herein mean that a photoresist film containing silicon that is a lower concept is also included.

That is, the present invention provides a method for processing a semiconductor wafer, comprising at least: a first step of cleaning treatment, using an ammonia aqueous solution, of a surface exposed by removing an organic film containing silicon formed on the semiconductor wafer substrate; and a second step of cleaning treatment, using a diluted fluorinated acid aqueous solution.

Further, the present invention provides a method for processing a semiconductor wafer, comprising at least: a step of sequentially applying a lower layer organic film, an organic film containing silicon and a photoresist not containing silicon on the semiconductor wafer substrate; a step of exposing and developing the photoresist; a step of removing the photoresist by a thinner treatment; a step of removing the organic film containing silicon by plasma etching using a fluorocarbon gas; a step of ashing treatment by oxygen plasma to remove the lower layer organic film; a first step of cleaning treatment, using an ammonia aqueous solution; and a second step of cleaning treatment, using a diluted fluorinated acid aqueous solution.

According to the present invention, in a repeated step, that is so-called “rework process”, in a lithography step in which an organic film containing silicon or a photoresist containing silicon is used, there can be provided an unprecedented advantage that sufficient removal of silicon compound residues is allowed. Therefore, when the present invention is applied to manufacture of a semiconductor device, there can be provided an advantage that a highly reliable semiconductor device can be manufactured even if carrying out a rework process in a lithography step. Further, there can be provided an advantage that the metal will not be dissolved even if a metal film such as tungsten, aluminum or titanium is present in a lower layer.

### BRIEF DESCRIPTION OF THE DRAWINGS

FIGS. 1A to 1D are cross-sectional views illustrating the first exemplary embodiment of the present invention;

FIGS. 2A to 2E are cross-sectional views illustrating the second exemplary embodiment of the present invention;

FIGS. 3A to 3C are cross-sectional views illustrating one exemplary embodiment of a related art; and

FIGS. 4A to 4D are cross-sectional views illustrating one exemplary embodiment of a related art.

### DETAILED DESCRIPTION OF THE PREFERRED EMBODIMENTS

Now, exemplary embodiments of the present invention will be hereinafter described with reference to the accompanying drawings.

### First Exemplary Embodiment

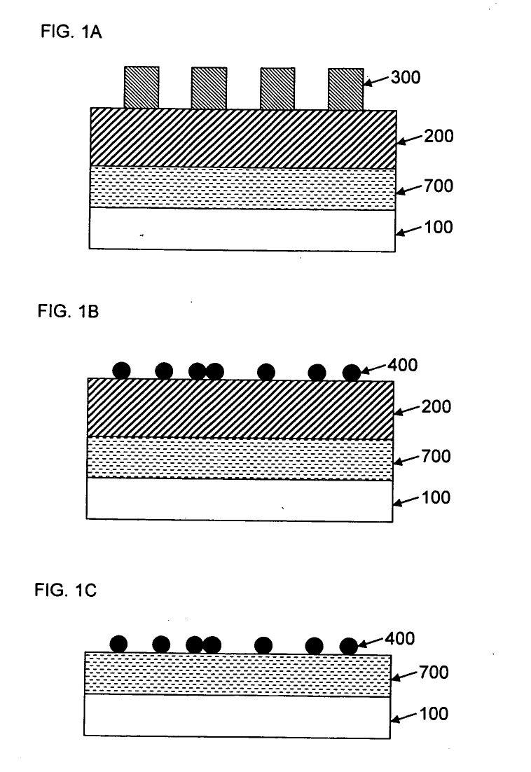

FIGS. 1A to 1D show cross-sectional views illustrating main steps in their order for explaining the first exemplary embodiment of the present invention. Specifically, the drawings show cross-sectional views illustrating steps in sequence in which the present invention is applied to a removal process for rework in a bilayer process in which a lower layer organic film and a photoresist containing silicon as an organic film containing silicon are used.

FIG. 1A shows a state after forming a work film 700 to be processed that is a metal film for constituting wirings such as tungsten, aluminum or titanium, or an insulating film such as a silicon oxide film on a semiconductor wafer 100, applying a lower layer organic film 200 and a photoresist containing silicon 300, and exposing and developing the photoresist containing silicon 300. At this time, silicon compound residues have yet not been generated.

Here, in the present exemplary embodiment, a silicon monocrystal wafer was used as the semiconductor wafer 100, and a metal film or a silicon oxide film was formed by a well known method. For example, the film was formed by chemical vapor deposition (CVD) method. Further, the lower layer organic film 200 was applied on the surface of the semiconductor wafer 100 by spin application, and burned at 200° C. for 60 sec to form the lower layer organic film 200 having a film thickness of 300 nm. As the lower layer organic film 200, there may be used, for example, a film having polyhydroxystyrene resin as a main component and prepared by adding a crosslinking agent etc. to an organic solvent such as propylene glycol monomethyl ether acetate or ethyl lactate.

Further, the photoresist containing silicon 300 was applied on the surface of the lower layer organic film 200 by spin application, and burned at 85° C. for 60 sec to provide the photoresist containing silicon 300 having a film thickness of 100 nm. Subsequently, it was exposed by a scan exposure apparatus and developed. As the photoresist containing silicon 300, for example, a polysiloxane chemical amplification resist, or in addition to this, a polysilane resist, a carbosilane resist, an acrylic polymer resist having a functional group containing silicon, or a resist prepared by mixing two or more of these resists may be used. The polysiloxane chemical amplification resist may include, for example, a resist prepared by blending a chemical amplification resist composed of a resist composition having a silicon atom in a main chain and using siloxane polymer containing an acid decomposition group such as an acetal structure, an ester structure, a butyloxycarbonyl structure, and a photoacid generator, with a polysiloxane having a silicon atom in a main chain and containing a silanol structure in a molecule.

For exposure, a step and scan exposure apparatus or a step and repeat exposure apparatus may be used, and as a projection system, a reduced projection system or an equi-magnification projection system may be used. Alternatively, an electron-beam lithography system may be used. A g-ray (wavelength: 436 nm), an i-ray (wavelength: 365 nm), a KrF excimer laser (wavelength: 248 nm), an ArF excimer laser (wavelength: 193 nm), an X-ray, or an electron beam (EB) and the like may be used as a light source for exposure.

Next, as shown in FIG. 1B, the photoresist containing silicon 300 is removed by thinner treatment. The thinner treatment is a step of dissolution removal of a photoresist using an organic solvent. As the organic solvent, for example, propylene glycol monomethyl ether acetate, propylene glycol monomethyl ether, γ-prolactin, ethyl lactate, isopropanol, or a mixture liquid thereof may be used. After undergoing the step, as shown in FIG. 1B, silicon compound residues 400 are generated on the surface of the lower layer organic film 200.

Next, as shown in FIG. 1C, the lower layer organic film 200 is removed by the step of oxygen plasma ashing treatment. The oxygen plasma ashing was performed using an oxygen gas at a gas pressure of 100 mTorr and an RF power of 150 W for 60 sec. Also after the step of oxygen plasma ashing treatment, the silicon compound residues 400 generated in the step in FIG. 1B are not removed but remain on the work film 700 to be processed. At this time, it is thought that the silicon compound residues 400 are somewhat oxidized by the oxygen plasma.

Subsequently, as shown in FIG. 1D, a cleaning treatment is carried out using an ammonia aqueous solution prepared by mixing ammonia (NH₃) and water (H₂O), and a cleaning treatment is carried out using a diluted fluorinated acid aqueous solution prepared by mixing fluorinated acid (HF) and water (H₂O). By the cleaning treatment using the ammonia aqueous solution and the cleaning treatment using the diluted fluorinated acid aqueous solution, the silicon compound residues 400 are removed.

Here, as the cleaning treatment using the ammonia aqueous solution, an ammonia aqueous solution having an ammonia concentration of equal to or more than 0.01 weight percent and equal to or less than 30 weight percent is preferably discharged onto the rotated work film 700 to be processed, using a cleaning apparatus of single wafer system. More preferably, an ammonia aqueous solution having an ammonia concentration of equal to or more than 10 weight percent and equal to or less than 30 weight percent may be used. In the present exemplary embodiment, an ammonia aqueous solution having an ammonia concentration of 10 weight percent was used at a temperature of 25° C. and a flow of 2 L/min for 30 sec. In addition, the ammonia aqueous solution may have an adequate chelating agent and/or an surface active agent mixed therewith.

Then, as the cleaning treatment using the diluted fluorinated acid aqueous solution, a diluted fluorinated acid aqueous solution having a fluorinated acid concentration of equal to or more than 0.01 weight percent and equal to or less than 2.0 weight percent is preferably discharged onto the rotated semiconductor wafer 100, using a cleaning apparatus of single wafer system. More preferably, a diluted fluorinated acid aqueous solution having a fluorinated acid concentration of equal to or more than 0.1 weight percent and equal to or less than 1.0 weight percent may be used. In the present exemplary embodiment, a fluorinated acid aqueous solution having a fluorinated acid concentration of 0.5 weight percent was used at a temperature of 25° C. and a flow of 2 L/min for 30 sec.

By carrying out these steps, the silicon compound residues 400 can be removed to provide a clean surface of the work film 700 to be processed, as shown in FIG. 1D.

Subsequently, a lower layer organic film and a photoresist containing silicon are again applied to proceed to a lithography step for rework (not shown).

In this rework process, as the result of application of the present invention, the silicon compound residues are not present, and the silicon compound residues do not form an obstacle to exposure and a bit of dust in a subsequent process, so that failure in the process due to the silicon compound residues can be avoided. Further, even when the work film 700 to be processed is a metal film such as tungsten or aluminum, upon removing silicon compound residues 400, pollution due to dissolution of the work film to be processed 700 does not occur.

### Second Exemplary Embodiment

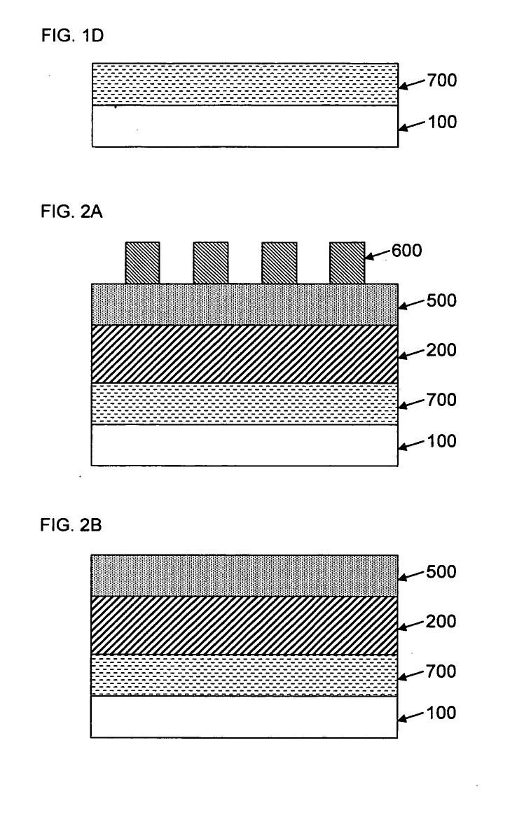

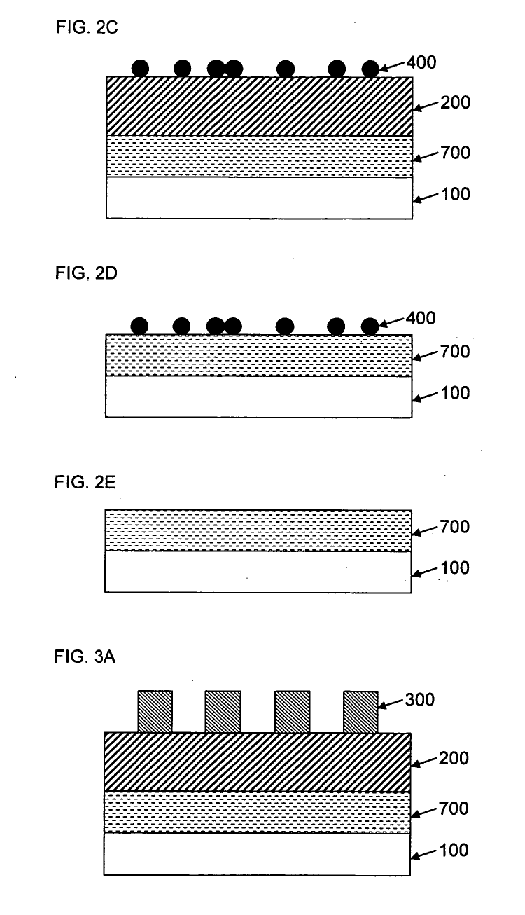

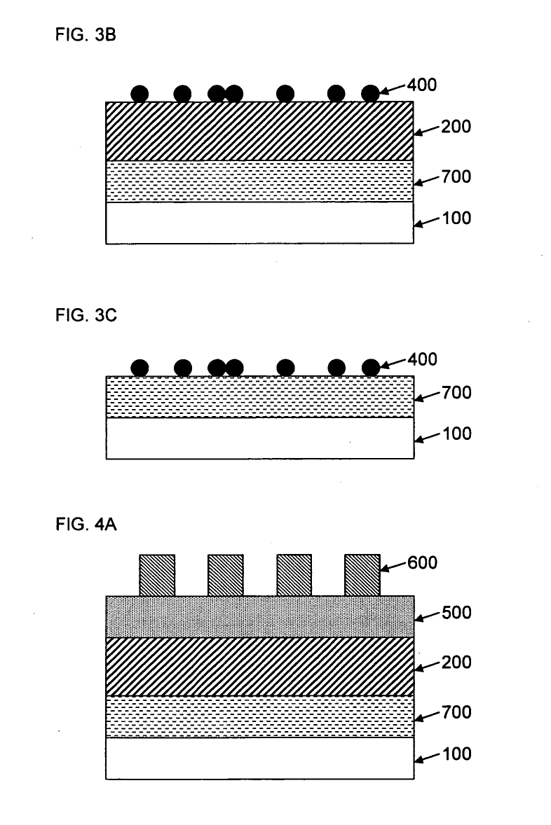

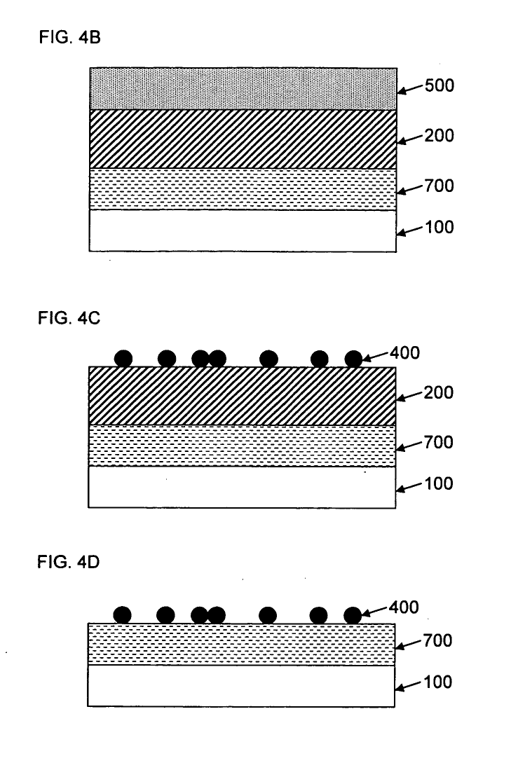

FIGS. 2A to 2E show cross-sectional views illustrating main steps in their order for explaining the second exemplary embodiment of the present invention. Specifically, the drawings show cross-sectional views illustrating steps in sequence in which the present invention is applied to a removal process for rework in a multilayer resist process in which a lower layer organic film, an organic film containing silicon and a photoresist are used.

FIG. 2A shows a state after forming a work film 700 to be processed that is a metal film for constituting wirings such as tungsten, aluminum or titanium, or an insulating film such as a silicon oxide film on a semiconductor wafer 100, applying a lower layer organic film 200, an organic film containing silicon 500 and a photoresist not containing silicon 600, and exposing and developing the photoresist not containing silicon 600. At this time, silicon compound residues have yet not been generated.

Here, in the present exemplary embodiment, a silicon monocrystal wafer was used as the semiconductor wafer 100, and a metal film or a silicon oxide film was formed by a well known method. For example, the film was formed by chemical vapor deposition (CVD) method. Further, the lower layer organic film 200 was applied on the surface of the semiconductor wafer 100 by spin application, and burned at 200° C. for 60 sec to form the lower layer organic film 200 having a film thickness of 200 nm. As the lower layer organic film 200, there may be used, for example, a film having polyhydroxystyrene resin as a main component and prepared by adding a crosslinking agent etc. to an organic solvent such as propylene glycol monomethyl ether acetate or ethyl lactate.

Further, the organic film containing silicon 500 was applied on the surface of the lower layer organic film 200 by spin application, and burned at 85° C. for 60 sec to provide the organic film containing silicon 500 having a film thickness of 200 nm. As the organic film containing silicon 500, a polysiloxane organic film, a polysilane organic film, a carbosilane organic film, an acrylic polymer organic film having a functional group containing silicon, and an organic film prepared by mixing two or more of them, or an organic composition prepared by blending an organic composition composed of novolak resin or acrylic polymer with polysiloxane or polysilane, and the like may be used.

Further, the photoresist not containing silicon 600 was applied on the surface of the organic film containing silicon 500 by spin application, and burned at 85° C. for 60 sec to provide the photoresist not containing silicon 600 having a film thickness of 100 nm. In addition, for the photoresist not containing silicon 600, a conventional resist not containing silicon may be used. Subsequently, it was exposed by a scan exposure apparatus and developed. For exposure, a step and scan exposure apparatus or a step and repeat exposure apparatus may be used, and as a projection system, a reduced projection system or an equi-magnification projection system may be used. Alternatively, an electron-beam lithography system may be used. A g-ray (wavelength: 436 nm), an i-ray (wavelength: 365 nm), a KrF excimer laser (wavelength: 248 nm), an ArF excimer laser (wavelength: 193 nm), an X-ray, or an electron beam (EB) and the like may be used as a light source for exposure.

Next, as shown in FIG. 2B, the photoresist not containing silicon 600 is dissolved and removed by thinner treatment. Because the photoresist not containing silicon 600 does not contain silicon, even after undergoing the step, silicon compound residues are not generated.

Then, as shown in FIG. 2C, the organic film containing silicon 500 is etched and removed by plasma etching using a fluorocarbon gas.

The plasma etching using a fluorocarbon gas was performed using tetrafluorocarbon (CF₄) as an etching gas at a pressure of 80 mTorr, an RF power of 100 W, and a gas flow of 80 sccm, with a nitrogen gas being mixed as a diluted gas. As the other usable etching gases, there may be listed perfluorocarbon or hydrofluorocarbon. For example, in addition to tetrafluorocarbon, there may be trifluoromethane (CHF₃), hexafluoroethane (C₂F₆), tetrafluoroethane (C₂H₂F₄) and the like.

After undergoing this step, the silicon compound residues 400 are generated on the surface of the lower layer organic film 200.

Next, as shown in FIG. 2D, the lower layer organic film 200 is removed by the step of oxygen plasma ashing treatment. The oxygen plasma ashing was performed using an oxygen gas at a gas pressure of 100 mTorr and an RF power of 150 W for 60 sec. Also after the step of oxygen plasma ashing treatment, the silicon compound residues 400 generated in the step in FIG. 2C are not removed but remain on the work film 700 to be processed. At this time, it is thought that the silicon compound residues 400 are somewhat oxidized by the oxygen plasma.

Subsequently, as shown in FIG. 2E, a cleaning treatment is carried out using an ammonia aqueous solution prepared by mixing ammonia (NH₃) and water (H₂O), and a cleaning treatment is carried out using a diluted fluorinated acid aqueous solution prepared by mixing fluorinated acid (HF) and water (H₂O). By the cleaning treatment using the ammonia aqueous solution and the cleaning treatment using the diluted fluorinated acid aqueous solution, the silicon compound residues 400 are removed.

Here, as the cleaning treatment using the ammonia aqueous solution, an ammonia aqueous solution having an ammonia concentration of equal to or more than 0.01 weight percent and equal to or less than 30 weight percent is preferably discharged onto the rotated work film 700 to be processed, using a cleaning apparatus of single wafer system. More preferably, an ammonia aqueous solution having an ammonia concentration of equal to or more than 10 weight percent and equal to or less than 30 weight percent may be used. In the present exemplary embodiment, an ammonia aqueous solution having an ammonia concentration of 10 weight percent was used at a temperature of 25° C. and a flow of 2 L/min for 30 sec. In addition, the ammonia aqueous solution may have an adequate chelating agent and/or an surface active agent mixed therewith.

Then, as the cleaning treatment using the diluted fluorinated acid aqueous solution, a diluted fluorinated acid aqueous solution having a fluorinated acid concentration of equal to or more than 0.01 weight percent and equal to or less than 2.0 weight percent is preferably discharged onto the rotated semiconductor wafer 100, using a cleaning apparatus of single wafer system. More preferably, a diluted fluorinated acid aqueous solution having a fluorinated acid concentration of equal to or more than 0.1 weight percent and equal to or less than 1.0 weight percent may be used. In the present exemplary embodiment, a fluorinated acid aqueous solution having a fluorinated acid concentration of 0.5 weight percent was used at a temperature of 25° C. and a flow of 2 L/min for 30 sec.

By carrying out these steps, the silicon compound residues 400 can be removed to provide a clean surface of the work film 700 to be processed, as shown in FIG. 2E.

Subsequently, a lower layer organic film, an organic film containing silicon and a photoresist are again applied to proceed to a lithography step for rework (not shown).

In this rework process, as the result of application of the present invention, the silicon compound residues are not present, and the silicon compound residues do not form an obstacle to exposure and a bit of dust in a subsequent process, so that failure in a process due to the silicon compound residues can be avoided. Further, even when the work film 700 to be processed is a metal film such as tungsten or aluminum, upon removing silicon compound residues 400, pollution due to dissolution of the work film to be processed 700 does not occur.

### Experiments

Table 1 shows the experimental results for illustrating an advantage of the present invention.

The experiments include Experiment 1 to show comparison results of the case where the present invention is applied (after processing) with the case where the present invention is not applied (before processing), and Experiment 2 where only the treatment using the diluted fluorinated acid was carried out to further compare with the case of another chemical solution.

Experiment 1 was conducted using the film configuration as described in the first exemplary embodiment of the present invention described above. That is, the silicon oxide film, which is supposed to be the work film to be processed, was formed on the semiconductor wafer, and thereon, the lower layer organic film and the photoresist containing silicon were applied. The thinner treatment and the oxygen plasma ashing treatment were carried out and thereafter the cleaning treatment using the ammonia aqueous solution and the cleaning treatment using the diluted fluorinated acid aqueous solution were carried out. The processing conditions were that the cleaning treatment using the ammonia aqueous solution was carried out, using the cleaning apparatus of single wafer system, at the ammonia concentration of 10 weight percent, the temperature of 25° C., the flow of 2 L/min, and the treatment time of 30 sec; and the cleaning treatment using the diluted fluorinated acid aqueous solution was carried out, using the cleaning apparatus of single wafer system, at the fluorinated acid concentration of 0.5 weight percent, the temperature of 25° C., the flow of 2 L/min, and the treatment time of 30 sec.

On the other hand, Experiment 2 was conducted also using the film configuration as described in the first exemplary embodiment of the present invention described above. That is, the silicon oxide film, which is supposed to be the work film to be processed, was formed on the semiconductor wafer, and thereon, the lower layer organic film and the photoresist containing silicon were applied. The thinner treatment and the oxygen plasma ashing were carried out and thereafter only the cleaning treatment using the diluted fluorinated acid aqueous solution was carried out. The cleaning treatment using the diluted fluorinated acid aqueous solution was carried out, using the cleaning apparatus of single wafer system, at the fluorinated acid concentration of 0.5 weight percent, the temperature of 25° C. and the flow of 2 L/min, and the treatment time of 30 sec.

The experimental results were evaluated by counting up the numbers of silicon compound residues per semiconductor wafer before the processes and after the steps by a particle counter. As the semiconductor wafers, eight-inch silicon monocrystal wafers were used. The size of the particles to be counted up was from 0.1 to 1.0 μm. Three semiconductor wafers were used for each of Experiments 1 and 2, and the numbers of particles were counted up as the numbers of the silicon compound residues, and the reduction ratios of silicon compound residues each were calculated. The reduction ratio was calculated as follows:

{(the number of residues before processing)−(the number of residues after processing)}/(the number of residues before processing)×100(%)

In consequence, as the results of Experiment 1 for comparing the case where the present invention is applied (after processing) with the case where the present invention is not applied (before processing), any of the semiconductor wafers showed the reduction ratio exceeding 98%. On the contrary, as the results of Experiment 2 for comparison, the reduction ratios were approximately 78% to 88%. From the mentioned above, when applying the present invention, compared to the case where the present invention was not applied, it was found that it was allowed to remove the silicon compound residues by equal to or more than 98%. Further, compared to Experiment 2 in which only the cleaning treatment using the diluted fluorinated acid aqueous solution was carried out, it was found that the reduction ratios of the silicon compound residues were more superior by from about 10% to 20% or more.

TABLE 1

| | | the number of | the number of | reduction |
|---|---|---|---|---|
| | | residues before | residues after | ratio |
| | treatment | processing | processing | (%) |
| Experiment 1 | NH₃ aq. ↓ | 707 | 10 | 98.6 |
| | diluted HF | 456 | 8 | 98.2 |
| | aq. | 723 | 8 | 98.9 |
| Experiment 2 | diluted HF | 320 | 68 | 78.8 |
| | aq. | 205 | 25 | 87.8 |
| | | 483 | 67 | 86.1 |

As described above, applying the present invention, in a repeated step, that is so-called “rework process” in a photolithography step in which an organic film containing silicon or a photoresist containing silicon is used, there can be provided an unprecedented advantage that sufficient removal of silicon compound residues is allowed. Therefore, when the present invention is applied to manufacture of a semiconductor device, there can be provided an advantage that a highly reliable semiconductor device can be manufactured even if carrying out a rework process in a lithography step. Further, differing from the APM cleaning treatment or the SPM cleaning treatment, in the present invention, there can be provided an advantage that the metal will not be dissolved even if a metal film for forming wirings such as tungsten, aluminum or titanium is present in a lower layer.

What is claimed is:

1. A method for processing a semiconductor wafer, comprising at least:
a first step of cleaning treatment, using an ammonia aqueous solution, of a surface exposed by removing an organic film containing silicon formed on the semiconductor wafer substrate; and
a second step of cleaning treatment, using a diluted fluorinated acid aqueous solution.

2. The method for processing a semiconductor wafer according to claim 1, before the first step, further comprising:
a step of thinner treatment; and
a step of ashing treatment by oxygen plasma.

3. A method for processing a semiconductor wafer, comprising at least:
a step of sequentially applying a lower layer organic film, an organic film containing silicon and a photoresist not containing silicon on the semiconductor wafer substrate;
a step of exposing and developing the photoresist;
a step of removing the photoresist by a thinner treatment;
a step of removing the organic film containing silicon by plasma etching using a fluorocarbon gas;
a step of ashing treatment by oxygen plasma to remove the lower layer organic film;
a first step of cleaning treatment, using an ammonia aqueous solution; and
a second step of cleaning treatment, using a diluted fluorinated acid aqueous solution.

4. The method for processing a semiconductor wafer according to claim 1, wherein the organic film containing silicon is any one of a polysiloxane organic film, a polysilane organic film, a carbosilane organic film, an acrylic polymer organic film having a functional group containing silicon, and an organic film prepared by mixing two or more of them.

5. The method for processing a semiconductor wafer according to claim 1, wherein the organic film containing silicon is a photoresist film containing silicon.

6. The method for processing a semiconductor wafer according to claim 1, wherein the ammonia concentration of the ammonia aqueous solution is equal to or more than 0.01 weight percent and equal to or less than 30 weight percent.

7. The method for processing a semiconductor wafer according to claim 1, wherein the ammonia concentration of the ammonia aqueous solution is equal to or more than 10 weight percent and equal to or less than 30 weight percent.

8. The method for processing a semiconductor wafer according to claim 1, wherein the fluorinated acid concentration of the diluted fluorinated acid aqueous solution is equal to or more than 0.01 weight percent and equal to or less than 2.0 weight percent.

9. The method for processing a semiconductor wafer according to claim 1, wherein the fluorinated acid concentration of the diluted fluorinated acid aqueous solution is equal to or more than 0.1 weight percent and equal to or less than 1.0 weight percent.

10. The method for processing a semiconductor wafer according to claim 3, wherein the organic film containing silicon is any one of a polysiloxane organic film, a polysilane organic film, a carbosilane organic film, an acrylic polymer organic film having a functional group containing silicon, and an organic film prepared by mixing two or more of them.

11. The method for processing a semiconductor wafer according to claim 3, wherein the organic film containing silicon is a photoresist film containing silicon.

12. The method for processing a semiconductor wafer according to claim 3, wherein the ammonia concentration of the ammonia aqueous solution is equal to or more than 0.01 weight percent and equal to or less than 30 weight percent.

13. The method for processing a semiconductor wafer according to claim 3, wherein the ammonia concentration of the ammonia aqueous solution is equal to or more than 10 weight percent and equal to or less than 30 weight percent.

14. The method for processing a semiconductor wafer according to claim 3, wherein the fluorinated acid concentration of the diluted fluorinated acid aqueous solution is equal to or more than 0.01 weight percent and equal to or less than 2.0 weight percent.

15. The method for processing a semiconductor wafer according to claim 3, wherein the fluorinated acid concentration of the diluted fluorinated acid aqueous solution is equal to or more than 0.1 weight percent and equal to or less than 1.0 weight percent.
